(19) United States
(12) Patent Application Publication
(10) Pub. No.: US 2016/0011519 A1
(43) Pub. Date: Jan. 14, 2016

(54) LITHOGRAPHY APPARATUS AND ARTICLE MANUFACTURING METHOD

(71) Applicant: CANON KABUSHIKI KAISHA, Tokyo (JP)

(72) Inventors: Shigeki Ogawa, Utsunomiya-shi (JP); Hiroyoshi Kubo, Kawachi-gun (JP)

(21) Appl. No.: 14/793,551

(22) Filed: Jul. 7, 2015

(30) Foreign Application Priority Data
Jul. 11, 2014 (JP) 2014-143668

(51) Int. Cl. G03F 7/20; H01L 21/66

(52) U.S. Cl. CPC G03F 7/70058; H01L 22/20

(57) ABSTRACT

A lithography apparatus including a plurality of patterning devices each configured to perform patterning on a substrate includes a controller configured to perform assignment, based on information of an attribute of each of a plurality of lots each including one or more substrates, of the plurality of patterning devices to a plurality of substrates corresponding to the plurality of lots, and to cause the plurality of patterning devices to perform parallel processing for the plurality of substrates based on the assignment.

### BACKGROUND OF THE INVENTION

1. Field of the Invention

The present invention relates to a lithography apparatus and an article manufacturing method.

2. Description of the Related Art

A lithography apparatus (also referred to as a cluster type lithography apparatus) including a plurality of lithography units (also referred to as patterning devices) adapted to cooperate with a common substrate conveyance unit has been discussed (Japanese Unexamined Patent Application Publication (Translation of PCT Application) No. 2012-518898).

When the above described lithography apparatus performs parallel processing of a plurality of substrates for each substrate lot, if the total number of the substrates included in one lot is smaller than the total number of patterning devices included in the lot, some of the patterning devices may not be used during the parallel processing. This is disadvantageous in terms of the use efficiency of the lithography apparatus.

### SUMMARY OF THE INVENTION

The present invention is directed to, for example, a lithography apparatus advantageous in efficiency of use thereof.

According to an aspect of the present invention, a lithography apparatus including a plurality of patterning devices each configured to perform patterning on a substrate includes a controller configured to perform assignment, based on information of an attribute of each of a plurality of lots each including one or more substrates, of the plurality of patterning devices to a plurality of substrates corresponding to the plurality of lots, and to cause the plurality of patterning devices to perform parallel processing for the plurality of substrates based on the assignment.

Further features of the present invention will become apparent from the following description of exemplary embodiments with reference to the attached drawings.

### BRIEF DESCRIPTION OF THE DRAWINGS

FIG. 1 illustrates a configuration example of a part of a lithography apparatus according to an exemplary embodiment of the present invention.

FIG. 2 illustrates a configuration example of a lithography apparatus according to a first exemplary embodiment of the present invention.

FIG. 3 illustrates a flow of processing of a main controller.

FIG. 4 illustrates a configuration example of a lithography apparatus according to a third exemplary embodiment of the present invention.

FIG. 5 illustrates another configuration example of the lithography apparatus according to the third exemplary embodiment of the present invention.

### DESCRIPTION OF THE EMBODIMENTS

Exemplary embodiments of the present invention will be described below with reference to the accompanying drawings. Through all the drawings for describing the exemplary embodiments, the same members are assigned the same reference numerals in principle (unless otherwise noted), and description thereof is not repeated.

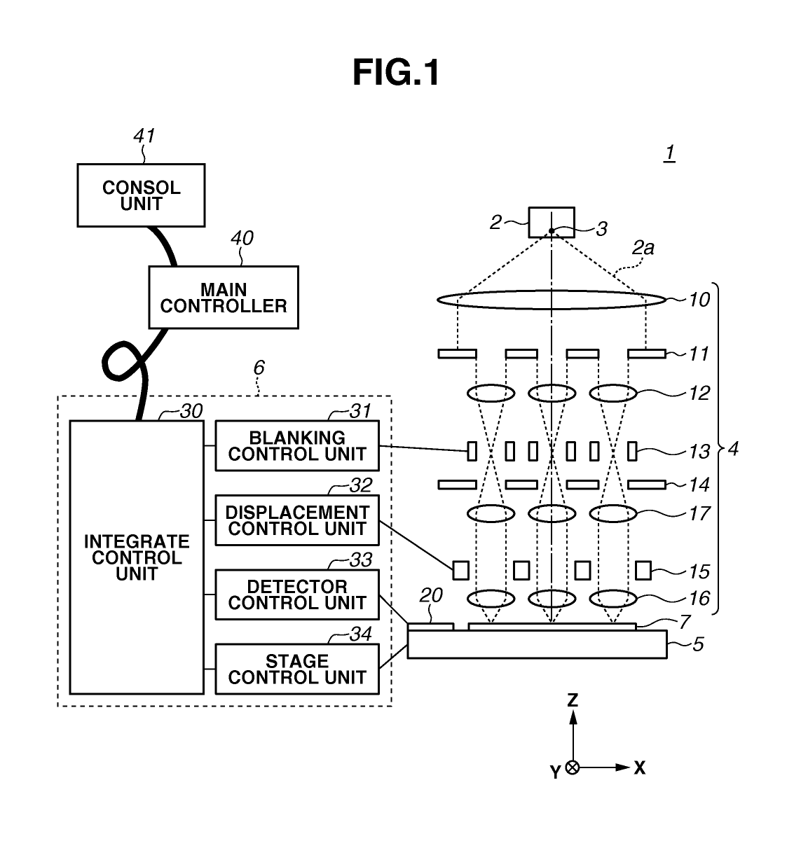

A first exemplary embodiment will be described below. FIG. 1 illustrates a configuration example of a part of a lithography apparatus according to the present exemplary embodiment. The lithography apparatus according to the present exemplary embodiment includes a plurality of patterning devices (also referred to as lithography units or devices) each capable of forming a pattern (patterning) on a substrate. The patterning device forms a (latent image) pattern on (a resist on) the substrate using a charged particle beam. While an electron beam as the charged particle beam is described below, other charged particle beams such as an ion line can also be used. However, the lithography apparatus is not limited to that. Any known lithography apparatus may be used. For example, the lithography apparatus may be an exposure apparatus that performs patterning on a substrate by projection and scanning with at least either one of an electromagnetic wave or light such as ultraviolet rays or X rays, or an imprint apparatus that performs patterning on a substrate by imprinting.

In FIG. 1, a patterning device 1 can include an electron gun 2, an optical system 4 (also referred to as an electron optical system or a charged particle optical system) that modulates an electron beam emitted from a crossover 3 formed in the electron beam 2, a stage 5 that holds a substrate 7, and a sub-controller 6. The substrate 7 can be a single crystal silicon wafer having its surface coated with a photoresist (merely referred to as a resist), for example. In FIG. 1, a Z-axis is provided parallel to an (optical) axis of the optical system 4, and an X-axis and a Y-axis perpendicular to each other are provided to be perpendicular to the Z-axis. A vacuum chamber and an exhaust or evacuation system (not illustrated) is configured to exhaust a gas from or evacuate the atmosphere of a path of the electron beam in the patterning device 1.

A track of an electron from the crossover 3 in the electron gun 2 is indicated by a broken line 2a. The optical system 4 includes a collimator lens 10, an aperture array 11, a first electrostatic lens array 12, a blanking deflector array 13, a blanking aperture array 14, a deflector array 15, and a second electrostatic lens array 16 in this order from the side of the electron gun 2. The optical system 4 may include a third electrostatic lens array 17 behind the blanking aperture array 14, and this case is illustrated in FIG. 1. The collimator lens 10 is an optical element for collimating the electron beam emitted from the crossover 3. The aperture array 11 is an optical element having a plurality of (circular) openings formed therein, for dividing the electron beam from the collimator lens 10 into a plurality of electron beams. The first electrostatic lens array 12 is an optical element including three electrode plates each having a plurality of (circular) openings formed therein (a schematic view in FIG. 1), for example, which form a plurality of crossovers on the blanking deflector array 13. The blanking deflector array 13 and the blanking aperture array 14 are respectively optical elements, having a plurality of deflectors and a plurality of openings formed therein, which switch between irradiation (a non-blanking state) and non-irradiation (a blanking state) of each of the electron beams onto the substrate 7. The blanking deflector array 13 and the blanking aperture array 14 are also collectively referred to as a blanking unit. The blanking unit is not limited to a transmission type device that performs blanking by preventing an electron beam from transmitting, as described above. The blanking unit can be employed as long as it has a function of blanking an electron beam. For example, the blanking unit may be a reflection type device (described below) that performs blanking by preventing reflection of an electron beam. The third electrostatic lens array 17 is an optical element for collimating each of the electron beams. The deflector array (deflector) 15 is an optical element for displacing the electron beam along the X-axis on the substrate 7 held on the stage 5. The second electrostatic lens array 16 is an optical element for focusing the electron beam, which has passed through the blanking aperture array 14, onto the substrate 7. A detector 20 is provided on the stage 5, and detects the electron beam that has been focused by the second electrostatic lens array 16. The sub-controller 6 can measure an image of the crossover 3 (an intensity distribution of the electron beam) based on an output of the detector 20.

The stage 5 holds the substrate 7 with an electrostatic force, for example, and enables positioning of the substrate 7 at a 6-degree-of-freedom. The positioning can be controlled when a measurement device (e.g., interferometer) (not illustrated) measures a position of the stage 5. The sub-controller 6 controls the position of the stage 5. An intensity distribution of the electron beam is obtained based on information about the position and an output signal (electric signal) of the detector 20.

The sub-controller 6 includes lower controllers that control operations of components related to the patterning by the patterning device 1 and an upper integrate control unit 30 that presides over the lower control units. The sub-controller 6 includes a blanking control unit 31, a displacement control unit 32, a detector control unit 33, and a stage control unit 34 as the lower control units. The sub-controller 6 may also include a lens control unit (not illustrated) that controls operations of the collimator lens 10 and the electrostatic lens arrays 12, 16, and 17. The blanking control unit 31 controls an operation of the blanking deflector array 13 based on a blanking signal. The integrate control unit 30 can generate the blanking signal based on designed device pattern data. The displacement control unit 32 controls an operation of the deflector array 15 based on a deflection signal. The integrate control unit 30 can generate the deflection signal.

The detector control unit 33 measures a characteristic of the electron beam based on an output from the detector 20. A measurement result is transmitted to the integrate control unit 30. The detector control unit 33 can measure the intensity distribution of the electron beam by cooperating with at least either one of the displacement control unit 32 and the stage control unit 34 via the integrate control unit 30. This measurement enables measurement of an intensity distribution (or a shape, a position, a total intensity, etc.) of the electron beam based on an output of the detector 20, a position of the stage 5, and a deflection amount (displacement amount) of the electron beam, for example.

The stage control unit 34 controls the position of the stage 5 based on a position instruction (target position) from the integrate control unit 30. The stage control unit 34 moves (scans) the stage 5 along the Y-axis to perform patterning. In parallel therewith, the deflector array 15 displaces the electron beam along the X-axis on the substrate 7 based on the position of the stage 5. In parallel, the blanking deflector array 13 blanks the electron beam so that a target dose is obtained on the substrate 7. The patterning device 1 has a function of measuring a position of an alignment mark formed on the substrate 7, and can perform patterning by overlaying a pattern on another pattern already formed on the substrate 7 based on a result of the measurement.

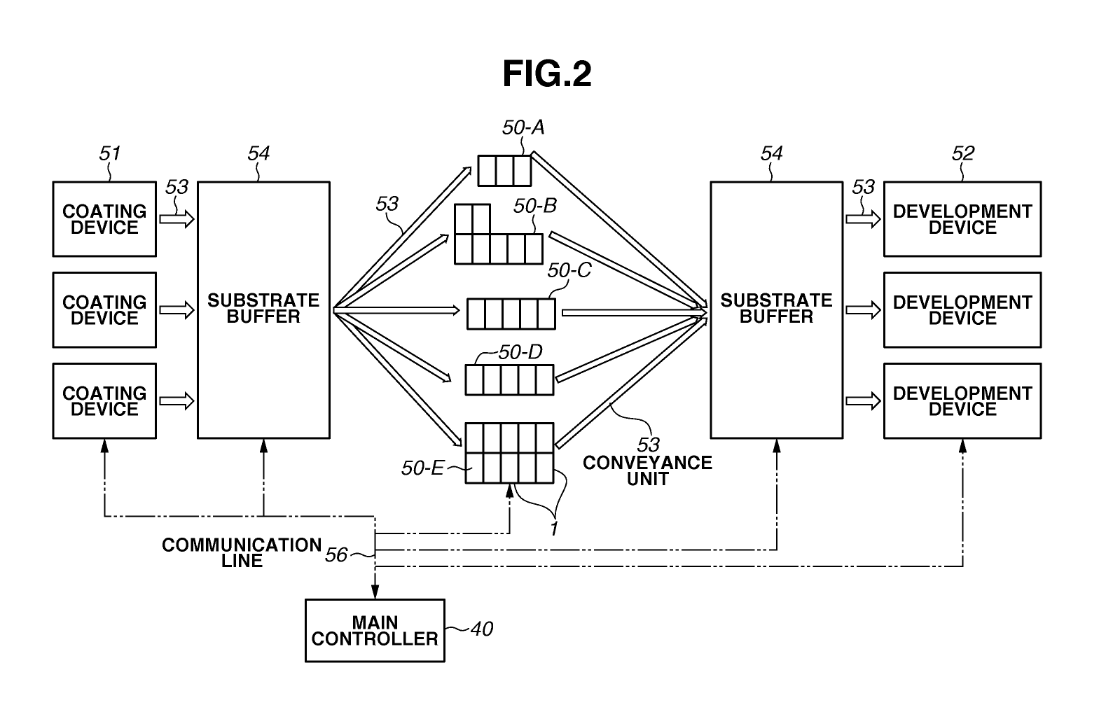

The patterning device 1 including the sub-controller 6 includes a plurality of patterning devices 1 as described below with reference to FIG. 2, to constitute a cluster type lithography apparatus. In FIG. 1, a main controller 40 is connected to the plurality of sub-controllers 6, and controls operations of the plurality of patterning devices 1. A console unit 41 is connected to the main controller 40, and provides a user interface to the lithography apparatus.

FIG. 2 illustrates a configuration example of the lithography apparatus according to the first exemplary embodiment. In FIG. 2, a patterning device group 50 (each of 50-A to 50-E) includes a plurality of patterning devices 1 described with reference to FIG. 1. The patterning device group 50 performs patterning on a plurality of substrates 7 belonging to a single lot in parallel using the plurality of patterning devices 1 which constitute the patterning device group 50. The number of substrates 7 to be processed per unit time by the patterning device 1 is multiplied by the number of the patterning devices 1 constituting the patterning device group 50, to determine the number of substrates 7 to be processed per unit time by each of the patterning device groups 50. More specifically, the number of substrates 7 to be processed per unit time by each of the patterning device groups 50 can be adjusted depending on the number of the patterning devices 1 belonging to the patterning device group 50.

The number of the patterning devices 1 constituting each of the patterning device groups 50 can be previously determined to match a production plan of an article (e.g., a semiconductor device) to be produced by the lithography apparatus, for example. The main controller 40 makes assignment of the patterning device group 50 that performs patterning on the plurality of substrates 7 belonging to each lot in parallel. The lithography apparatus can include the main controller 40, the patterning device groups 50, and (some of) conveyance units (conveyance devices) 53 (each indicated by a hollow arrow). The main controller 40 can perform a necessary operation based on the assignment to control a flow of a series of processing including coating of the substrate 7 with a resist, supply of the substrate 7 coated with the resist to the patterning device group 50, and development of the (resist on) the substrate 7 on which the patterning has been performed. The main controller 40 communicates necessary information to the coating devices 51, development devices 52, and substrate buffers 54, for example, to cooperate with the devices.

FIG. 2 schematically illustrates a configuration in a case where processing (patterning) is performed on substrates 7 belonging to five lots in parallel. Therefore, the five patterning device groups 50-A to 50-E are assigned correspondingly to the five lots. When the number of substrates 7 to be processed per unit time by the patterning device 1 is ten, for example, the number of substrates 7 to be processed per unit time by the patterning device group 50-A including the three patterning devices 1 becomes 30. Similarly, the number of substrates 7 to be processed per unit time by the patterning device group 50-B including seven patterning devices 1 is 70, the number of substrates 7 to be processed per unit time by the patterning device groups 50-C and 50-D each including five patterning devices 1 is 50, and the number of substrates 7 to be processed per unit time by the patterning device group 50-E including ten patterning devices 1 is 100.

The coating device 51 coats the substrates 7 to be supplied to each of the patterning devices groups 50, with a resist. While the number of the coating devices 51 is three in FIG. 2, the number of the coating devices 51 is not limited to that if the sum of throughputs of the coating devices 51 is equal to or more than the sum of throughputs of the patterning device groups 50. While a communication line 56 (indicated by a two-dot chain line) is connected to only the one coating device 51 in FIG. 2, the communication line 56 is in practice connected to each of the coating devices 51. It is similar for the patterning device groups 50 and the development devices 52. Information about a lot (e.g., recipe information) required for processing in each of the devices can be sent to the device via the communication line 56. Information about a state of the devices (at least one of a schedule, a progress, and an abnormality (error) of processing) can be sent to the main controller 40 via the communication line 56.

The substrate 7 is temporarily stored in the substrate buffer 54 after being coated with the resist, and is then conveyed by the conveyance unit 53 to the patterning device group 50 that processes the substrate 7 under the control of the main controller 40. The conveyance of the substrate 7 may be controlled by communication via a communication line (not illustrated) between the substrate buffer 54 and (any one of the patterning devices 1 in) the patterning device group 50. The substrate 7 stored in the substrate buffer 54 is conveyed to the patterning device group 50 corresponding thereto via the conveyance unit 53 to match a processing timing of the patterning device group 50. The substrate 7, on which patterning has been performed in each of the patterning device groups 50, is conveyed to the substrate buffer 54 via the conveyance unit 53 and is temporarily stored therein. While the substrate buffers 54 are separately arranged at the right and the left of the patterning device group 50 in FIG. 2, they may be an identical (a single) substrate buffer. Then, the substrate 7 is conveyed by the conveyance unit 53 to the development device 52 that processes the substrate 7 under the control of the main controller 40. The conveyance of the substrate 7 may be controlled by communication via a communication line (not illustrated) between the substrate buffer 54 and the development device 52. The substrate 7 stored in the substrate buffer 54 is supplied to the development device 52 corresponding thereto via the conveyance unit 53 to match a processing timing of the development device 52. While the number of development devices 52 is three in FIG. 2, the number of development devices 52 is not limited to that and any number of development devices can be used as long as the sum of throughputs of the development devices 52 is equal to or more than the sum of throughputs of the patterning device groups 50.

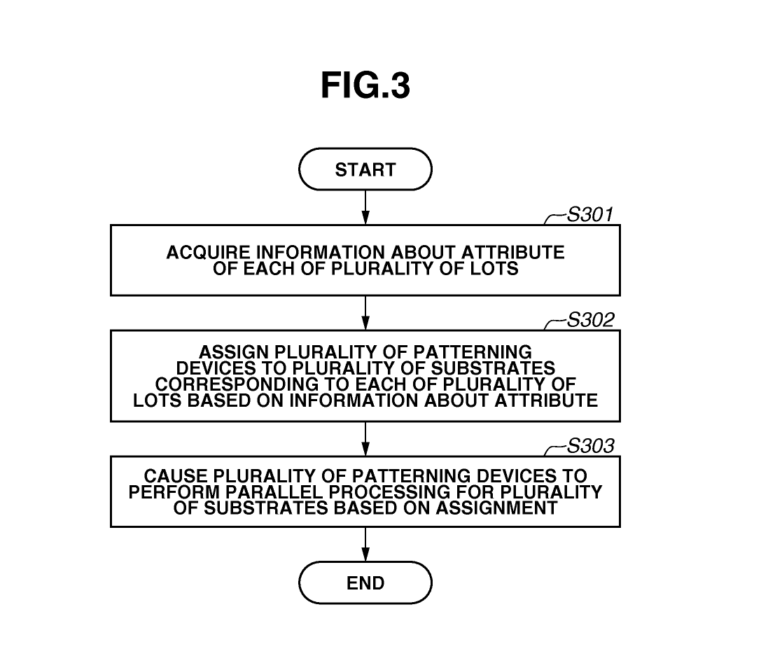

FIG. 3 illustrates a flow of processing of the main controller 40. The flow of processing of the main controller 40 will be described with reference to FIG. 3. If processing is started, then in step S301, the main controller 40 acquires information about an attribute of each of a plurality of lots each including one or more substrates 7 which are patterning targets. The information about an attribute can be acquired from information about a recipe corresponding to each of the lots, for example. The attribute includes the number of substrates 7 included in each of the lots. In step S302, the main controller 40 then makes assignment the plurality of patterning device groups 50, each of which processes in parallel the plurality of substrates 7 corresponding to the plurality of lots based on the acquired information about the attribute. In the assignment, the plurality of patterning devices 1 is assigned to the plurality of substrates 7 corresponding to each of lots. When the lithography apparatus performs parallel processing of the plurality of substrates 7 for each of the lots including the substrates 7, as described above, if the total number of the substrates 7 included in one of the lots is smaller than the total number of the patterning devices 1 included in the lot, some of the patterning devices 1 may not be used during the parallel processing. Thus, the lithography apparatus cannot be efficiently used. Therefore, the assignment is performed by preventing the patterning devices 1 from being unused, as much as possible during the parallel processing based on the number of the substrates 7 included in each of the lots. In the example illustrated in FIG. 2, the five patterning device groups 50-A to 50-E (the total number of the patterning devices 1 is 30) are respectively assigned to the five lots. For example, three patterning devices 1 are assigned to the first lot including three substrates. Similarly, seven patterning devices 1 are assigned to the second lot including seven substrates, five patterning devices are assigned to the third lot and the fourth lot each including five substrates, and ten patterning devices 1 are assigned to the fifth lot including ten substrates. In step S303, the main controller 40 causes the plurality of patterning devices 1 to perform parallel processing of the plurality of substrates 7 corresponding to the plurality of lots based on the assignment. In the example illustrated in FIG. 2, the main controller 40 causes the 30 patterning devices 1 (the five patterning device groups 50-A to 50-E) to process the 30 substrates 7 each belonging to any one of the five lots in parallel.

According to the present exemplary embodiment, the parallel processing is performed by preventing the plurality of patterning devices from being unused, as much as possible, for example. Thus, a lithography apparatus, which is advantageous in terms of its use efficiency, can be provided.

A second exemplary embodiment will be described with reference to FIGS. 1 to 3 already described above. The description is not repeated for items in common with those in the first exemplary embodiment. While an attribute of each lot includes the number of substrates belonging to each of the lots in the first exemplary embodiment, in the second exemplary embodiment, an attribute of each lot further includes an overlay characteristic on patterns formed on substrates 7 belonging to each of the lots. Each of patterning devices 1 has a specific characteristic that affects the overlay. The characteristics can include a characteristic of an optical system 4, a characteristic of a control system (including a measurement device) for positioning a stage 5, and a characteristic of a structure that supports at least either one of the optical system 4 or the stage 5. A plurality of patterning devices 1 (a patterning device group 50) that processes a plurality of substrates 7 belonging to the same lot includes patterning devices 1 that are identical or similar to each other in the characteristic. A main controller 40 makes assignment of the plurality of patterning devices 1 (the patterning device group 50).

A lithography apparatus according to the present exemplary embodiment is preferably adjusted, corrected, or compensated for so that a difference in characteristics among the plurality of patterning devices 1 is made as small as possible. However, a difference in characteristic actually remains even if the difference is slight. The difference in characteristic falls within an allowable range, and is thus normally at such a level that it does not become a problem. However, the patterning devices to be assigned are preferably limited depending on required overlay precision. Therefore, information about a characteristic related to overlay of each of the patterning devices 1 may be previously acquired, for example, to store the information in the main controller 40 or other storage units. The main controller 40 can determine the patterning device group 50 (a combination of the patterning devices 1 corresponding to each of the lots) based on the information and the overlay precision.

The main controller 40 may make the attribute, which is acquired in step S301 illustrated in FIG. 3, include not only the number of substrates 7 belonging to each of the lots but also an overlay characteristic (e.g., required overlay precision) on the patterns formed on the substrates 7 belonging to each of the lots. Assignment in step S302 may be performed based on information about the attribute.

According to the present exemplary embodiment, a lithography apparatus that is advantageous in terms of not only its use efficiency but also overlay precision, for example, can be provided.

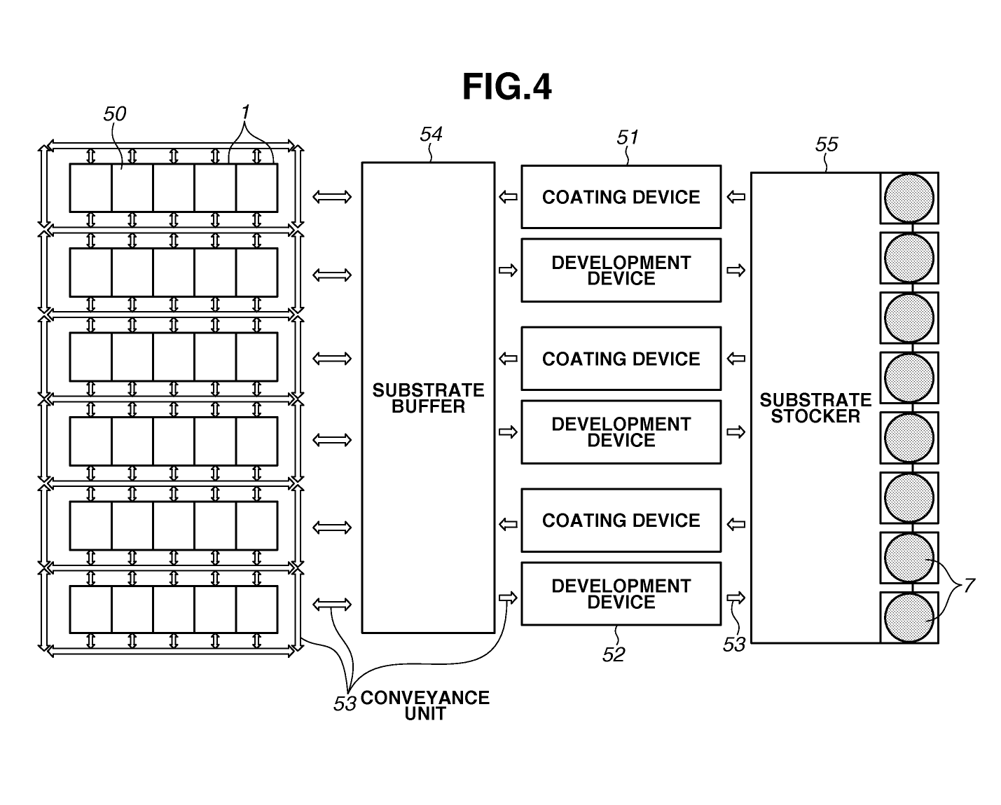

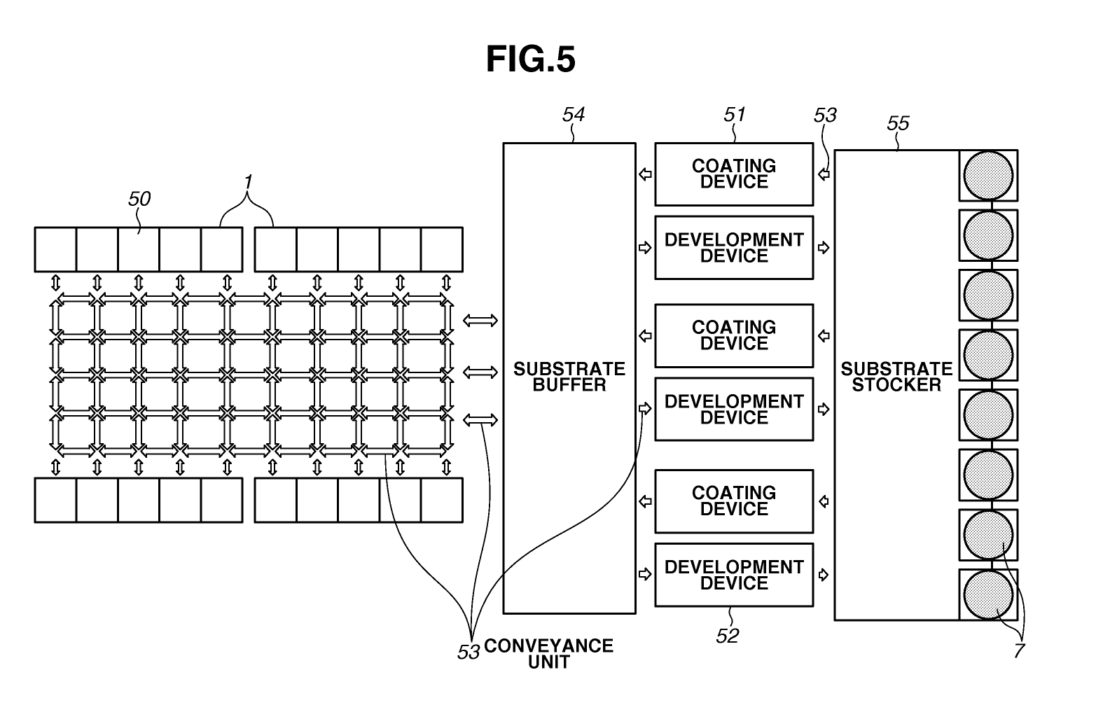

FIGS. 4 and 5 illustrate a configuration of a lithography apparatus according to a third exemplary embodiment. The third exemplary embodiment will be described with reference to FIGS. 4 and 5. A configuration of a conveyance unit 53 in FIG. 4 differs from that illustrated in FIG. 2. While each of patterning device groups 50 includes five patterning devices 1 in FIG. 4, the number of patterning devices 1 in each of the patterning device groups 50 is not limited to that. In FIG. 4, a conveyance unit 53 is arranged around the patterning device groups 50 to surround the patterning device groups 50. When the conveyance unit 53 is thus configured, a conveyance path of a substrate 7 from a substrate buffer 54 to the target patterning device 1 can include a plurality of types of conveyance paths. Accordingly, even if an error occurs in some of the conveyance paths, the substrate 7 can be conveyed via the other conveyance paths. Thus, robustness of the conveyance unit 53 is enhanced. Such a configuration of the conveyance unit 53 enables easy changing of the number of patterning devices 1 constituting the patterning device group 50. The configuration of the conveyance unit 3, which is advantageous in terms of robustness, can also be implemented by a configuration illustrated in FIG. 5. In FIG. 5, a conveyance unit 53 has its conveyance paths configured (formed) in a network shape (in a net shape). The configuration of the conveyance paths is not limited to those in configuration examples illustrated in FIGS. 4 and 5, and can be determined in consideration of an arrangement space and cost as long as it enhances robustness of the conveyance unit 53.

In the foregoing description, the attribute, which is acquired in step S301 illustrated in FIG. 3, includes the number of substrates belonging to each of the lots and in addition an overlay characteristic (e.g., required overlay precision) on patterns formed on the substrates belonging to each of the lots. However, the attribute is not limited to those, and may include the following attributes:
Not “in addition to the number of substrates belonging to each of the lots” but only an overlay characteristic (e.g., required overlay precision) on patterns formed on the substrates belonging to each of the lots
a required time allowed for processing (patterning) of each of the lots
a priority of processing (patterning) of each of the lots

The second attribute (required time) is advantageous, for example, when there is a time constraint in use of a resist applied to the substrate. The last attribute is advantageous for, but is not limited to, performance of a production plan of an article. For example, with respect to the upper three lots given higher priorities (each of the lots includes ten substrates), the 30 patterning devices 1 illustrated in FIG. 4 can perform parallel processing of the 30 substrates corresponding to the three lots. More specifically, the number of patterning devices 1 assigned per lot is variable. When throughput of each of the patterning devices 1 is ten substrates per hour, throughputs of 10 to 300 substrates per hour can be selected, by units of ten substrates for each of the lots. When a maskless lithography apparatus to perform patterning using a charged particle beam such as an electron line is adopted for the patterning devices 1, masks corresponding to the number of patterning devices 1 used for parallel processing of each of the lots need not be previously prepared. If a lithography apparatus using masks is adopted for the patterning devices 1, the number of masks usable for processing of each of the lots is suitably included in the attribute, which is acquired in step S301 illustrated in FIG. 3. The priority can be information about time when processing of each of the lots is to be completed.

The adoption of the priority as the attribute is also advantageous for a case where there is a request to interrupt processing of a high-priority lot including one or more substrates to be processed (a case where the interruption occurs in the production plan). In such a case, the main controller 40 may perform processing for each interruption in steps S301 and S302 again between the lots on which parallel processing is currently performed and the (plurality of) interruption-requested lots with respect to the patterning devices 1 constituting the patterning device group 50. Parallel processing in step S303 subsequent to steps S301 and S302 may be performed for the substrates that have not yet been processed in each of the lots. Thus, processing of the interruption-requested lot can be quickly started without stopping processing of the plurality of lots, which are in parallel processing, while the productivity thereof deteriorates.

An article manufacturing method in the exemplary embodiment of the present invention can be preferably used to manufacture an article such as a micro- or nano-device or an element having a fine structure, e.g., a semiconductor device. The article manufacturing method according to the present exemplary embodiment can include a process for performing patterning on a substrate and processing (e.g., developing) of a substrate on which patterning has been performed in the process using the above described lithography apparatus. Further, the manufacturing method can include other well-known processes (oxidation, film formation, evaporation, doping, flattening, etching, resist stripping, dicing, bonding, packaging, etc.). The article manufacturing method according to the present exemplary embodiment is more advantageous in at least one of performance, quality, productivity, and production cost of the article than a conventional method.

The exemplary embodiments of the present invention have been described above, however, the present invention is not limited to the exemplary embodiments. Various modifications and alterations can be made without departing from the scope of the present invention.

While a blanking unit (blanker array) including an array of electrode pairs has been illustrated that can be individually driven in the foregoing description, any blanking unit may be employed as long as it is an array of elements having a blanking function. For example, the blanking unit can include a reflective electron patterning device as discussed in U.S. Pat. No. 7,816,655. The device includes a pattern on its top surface, an electron reflecting portion in the pattern, and an electron non-reflecting portion in the pattern. The device further includes an array of circuitry for dynamically changing the electron reflecting portion and the electron non-reflecting portion in the pattern using a plurality of independently controllable pixels. Thus, the blanking unit may be an array of elements (blankers) for blanking a charged particle beam by changing the reflecting portion on the charged particle beam to the non-reflecting portion. A charged particle optical system including such a reflective device and a charged particle optical system including a transmissive device such as an array of electrode pairs can naturally be configured to differ from each other.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-143668, filed Jul. 11, 2014, which is hereby incorporated by reference herein in its entirety.

1. A lithography apparatus comprising a plurality of patterning devices each configured to perform patterning on a substrate, the apparatus comprising:
a controller configured to perform assignment, based on information of an attribute of each of a plurality of lots each including one or more substrates, of the plurality of patterning devices to a plurality of substrates corresponding to the plurality of lots, and to cause the plurality of patterning devices to perform parallel processing for the plurality of substrates based on the assignment.

2. The lithography apparatus according to claim 1, wherein the attribute includes number of the substrates belonging to each of the plurality of lots.

3. The lithography apparatus according to claim 1, wherein the attribute includes a characteristic of overlay for a pattern formed on the substrate belonging to each of the plurality of lots.

4. The lithography apparatus according to claim 1, wherein the attribute includes a required time allowed for processing of each of the plurality of lots.

5. The lithography apparatus according to claim 1, wherein the attribute includes a priority of processing of each of the plurality of lots.

6. The lithography apparatus according to claim 5, wherein the priority includes time at which processing of each of the plurality of lots should be completed.

7. The lithography apparatus according to claim 1, wherein the controller is configured to perform reassignment of the plurality of patterning devices, in a case where interruption is requested for processing of a lot including one or more substrates, based on information of an attribute of the lot processing of which the interruption is requested for, and to cause the plurality of patterning devices to perform parallel processing based on the reassignment.

8. The lithography apparatus according to claim 1, further comprising a conveyance device configured to convey a substrate to each of the plurality of patterning devices,
wherein the conveyance device is arranged around the plurality of patterning devices.

9. The lithography apparatus according to claim 1, further comprising a conveyance device configured to convey a substrate to each of the plurality of patterning devices,
wherein conveyance paths in the conveyance device are formed in a network.

10. A method of manufacturing an article, the method comprising steps of:
performing patterning on a substrate using a lithography apparatus; and
processing the substrate, on which the patterning has been performed, to manufacture the article,
wherein the lithography apparatus includes a plurality of patterning devices each configured to perform patterning on a substrate, and includes
a controller configured to perform assignment, based on information of an attribute of each of a plurality of lots each including one or more substrates, of the plurality of patterning devices to a plurality of substrates corresponding to the plurality of lots, and to cause the plurality of patterning devices to perform parallel processing for the plurality of substrates based on the assignment.
